(19) United States
(12) Patent Application Publication
(10) Pub. No.: US 2025/0351301 A1
(43) Pub. Date: Nov. 13, 2025

(54) LIQUID COOLING PLATE AND SERVER

(71) Applicant: WISTRON CORP., New Taipei City (TW)

(72) Inventors: HSIN YU YEN, New Taipei City (TW); YU TANG JU, New Taipei City (TW); YI HSUN LEE, New Taipei City (TW)

(21) Appl. No.: 18/792,969

(22) Filed: Aug. 2, 2024

(30) Foreign Application Priority Data
May 8, 2024 (TW) 113116978

(51) Int. Cl. H05K 7/20

(52) U.S. Cl. CPC H05K 7/20327; H05K 7/20809

(57) ABSTRACT

A liquid cooling plate includes a housing and a flexible partition. The housing has a fluid chamber, an inlet, an outlet and a recess, the inlet and the outlet communicate with the fluid chamber, and the recess is recessed from an inner surface of the fluid chamber. The flexible partition forms a gas chamber in the recess.

### CROSS-REFERENCE TO RELATED APPLICATIONS

This non-provisional application claims priority under 35 U.S.C. § 119(a) on Patent Application No(s). 113116978 filed in Taiwan, R.O.C. on May 8, 2024, the entire contents of which are hereby incorporated by reference.

### TECHNICAL FIELD

The disclosure relates to a liquid cooling plate and a server.

### BACKGROUND

In order to solve the problem that the liquid cooling plate is filled with coolant before transportation, causing the coolant to be frozen so as to have volume expansion during air transportation below 0° C., thereby damaging the liquid cooling plate and thus resulting in coolant leakage, the coolant should be discharged before transportation, or additional pipes are required to be connected to the liquid cooling plate for increasing space to accommodate the coolant. However, discharging coolant requires auxiliary system, which not only increases costs but also complicates the process. In addition, when transporting a large number of liquid cooling plates at the same time, connecting additional pipes causes overall weight and size to increase, and those pipes are only used during air transportation, which increases costs and consumes more manpower and time.

Although a coolant with a lower freezing point is used, and its freezing point is lower than the temperature during the air transportation, and thus the coolant will not freeze, but the characteristics of this coolant such as viscosity and thermal conductivity do not meet the requirements. Therefore, how to enable a coolant with desired viscosity and thermal conductivity (e.g., PG25) to be used while preventing the liquid cooling plate from being damaged is one of issues to be solved in this field.

### SUMMARY

The disclosure provides a liquid cooling plate and a server which enable a coolant with desired viscosity and thermal conductivity to be used while preventing the liquid cooling plate from being damaged.

One embodiment of the disclosure provides a liquid cooling plate. The liquid cooling plate includes a housing and a flexible partition. The housing has a fluid chamber, an inlet, an outlet and a recess, the inlet and the outlet communicate with the fluid chamber, and the recess is recessed from an inner surface of the fluid chamber. The flexible partition forms a gas chamber in the recess.

Another embodiment of the disclosure provides a server. The server includes a motherboard, a heat source and a liquid cooling plate. The heat source is disposed on the motherboard. The liquid cooling plate is thermally coupled to the heat source and includes a housing and a flexible partition. The housing has a fluid chamber, an inlet, an outlet and a recess, the inlet and the outlet communicate with the fluid chamber, and the recess is recessed from an inner surface of the fluid chamber. The flexible partition forms a gas chamber in the recess.

According to the liquid cooling plate and the server as discussed in the above embodiments, the liquid cooling plate is provided with the recess therein, and the flexible partition of the liquid cooling plate forms the gas chamber in the recess for accommodating the gas. Therefore, when the coolant in the liquid cooling plate is frozen, the frozen coolant forces the flexible partition to compress the gas in the gas chamber for absorbing the volume expansion of the coolant, thereby preventing the liquid cooling plate from being damaged by the frozen coolant which has volume expansion. As a result, even if the coolant is selected from a liquid which has better viscosity and thermal conductivity but higher freezing point so as to be easily frozen, the liquid cooling plate is ensured not to be damaged by the coolant which is frozen and has volume expansion.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a partial perspective view of a server and a cabinet according to a first embodiment of the disclosure;

FIG. 2 is a partial perspective view of the server in FIG. 1;

FIG. 3 is a partial exploded view of the server in FIG. 2;

FIG. 4 is an exploded view of a liquid cooling plate in FIG. 3;

FIG. 5 is a cross-sectional view of the liquid cooling plate in FIG. 3;

FIG. 6 is a cross-sectional view of the liquid cooling plate in FIG. 5 when a coolant in the liquid cooling plate is frozen;

FIG. 7 is a curve chart showing a relationship between specific volume of helium and temperature;

FIG. 8 is a curve chart showing a relationship between specific volume of water and temperature;

FIG. 9 is a curve chart showing a relationship between expansion rates of helium and water and temperature;

FIG. 10 is a cross-sectional view of a liquid cooling plate according to a second embodiment of the disclosure; and

FIG. 11 is a cross-sectional view of a liquid cooling plate according to a third embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

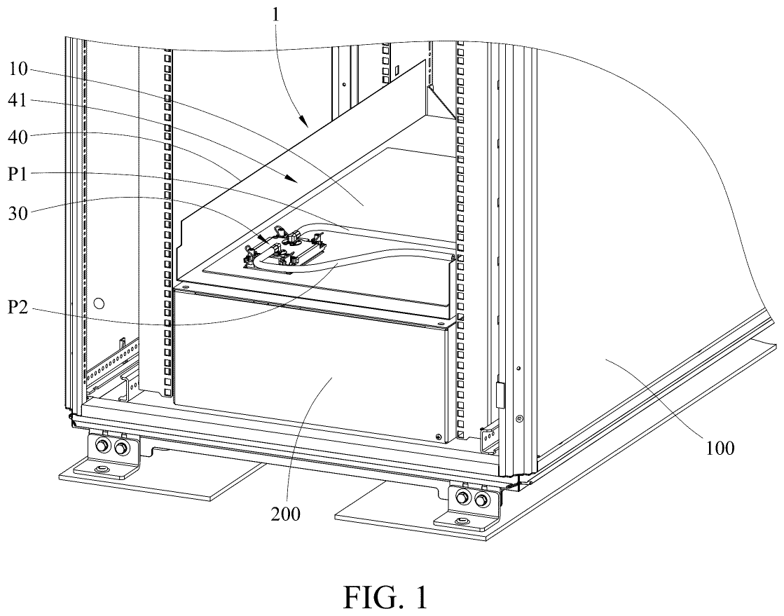

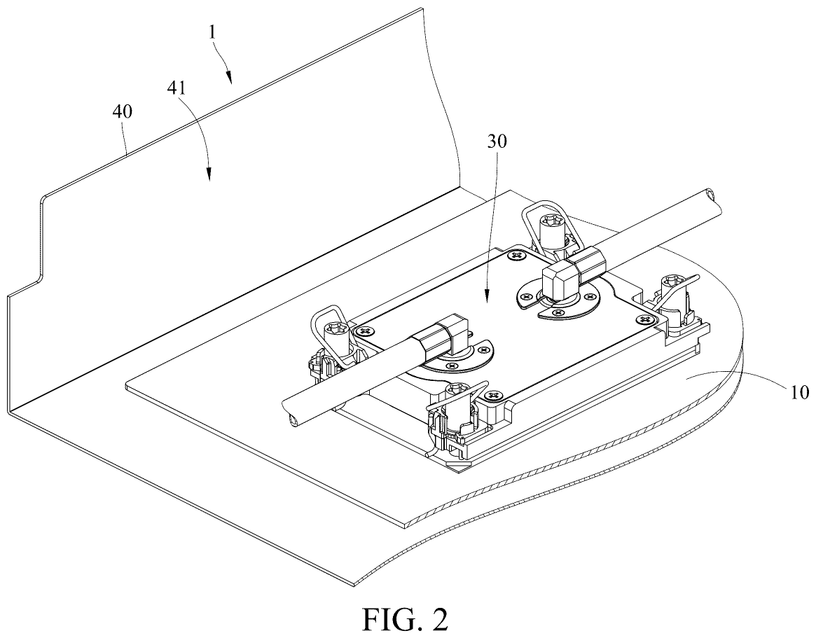

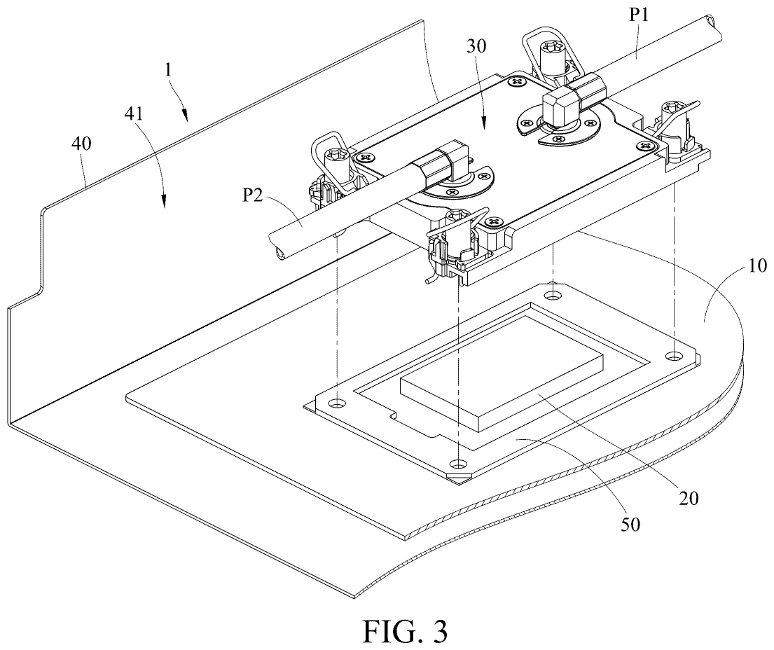

Referring to FIGS. 1 to 3, FIG. 1 is a partial perspective view of a server and a cabinet according to a first embodiment of the disclosure, FIG. 2 is a partial perspective view of the server in FIG. 1, and FIG. 3 is a partial exploded view of the server in FIG. 2.

In this embodiment, the server 1 is, for example, to be mounted in a cabinet 100. The server 1 includes a motherboard 10, a heat source 20 and a liquid cooling plate 30. In addition, the server 1 may further include a casing 40.

The casing 40 has an accommodation space 41. The motherboard 10 is located in the accommodation space 41 of the casing 40. The heat source 20 is, for example but not limited to, a CPU, and the heat source 20 is disposed on the motherboard 10. A mount seat 50 is disposed around the heat source 20 for the installation of the liquid cooling plate 30.

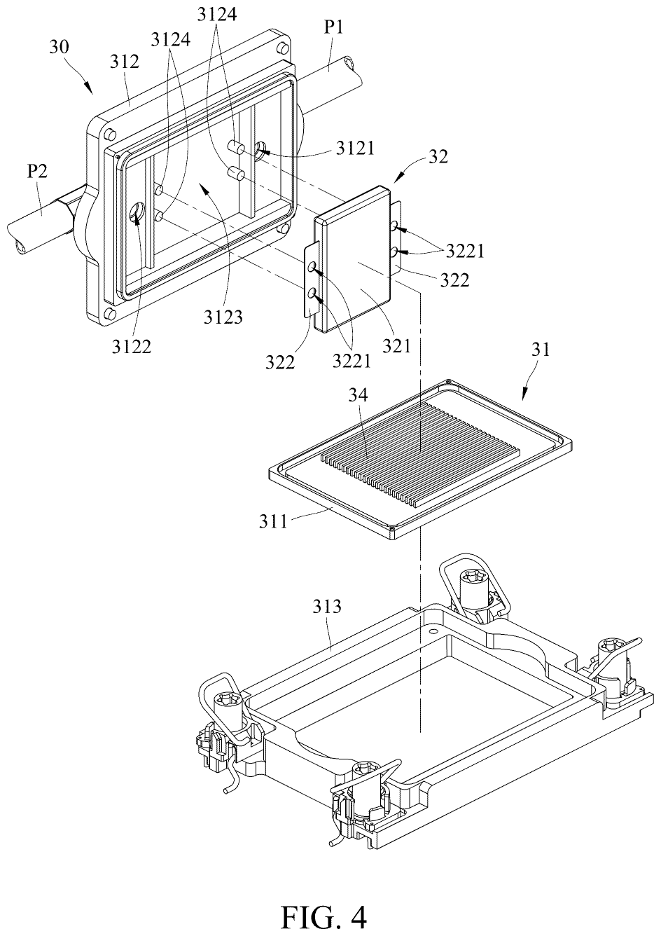

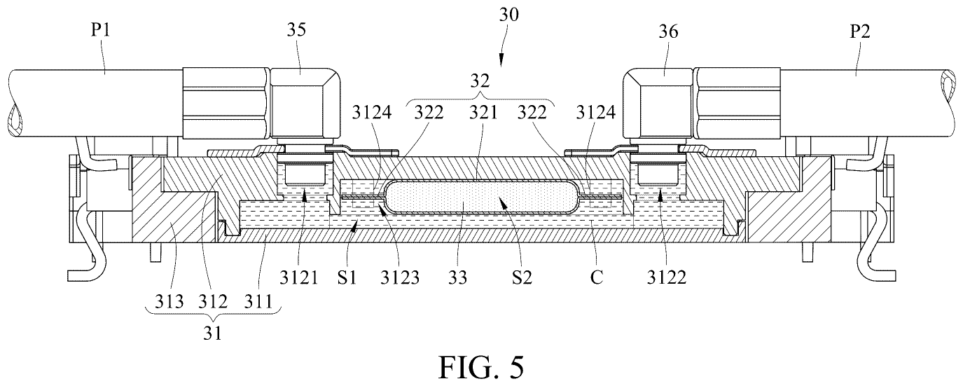

Specifically, FIGS. 3 to 5, FIG. 4 is an exploded view of a liquid cooling plate in FIG. 3, and FIG. 5 is a cross-sectional view of the liquid cooling plate in FIG. 3.

The liquid cooling plate 30 includes a housing 31 and a flexible partition 32. In addition, the liquid cooling plate 30 may further include a gas 33, a fin assembly 34 and two joints 35 and 36.

The housing 31 includes a base 311, a cover 312 and a mount frame 313. The base 311 and the cover 312 are assembled with each other, and the mount frame 313 is connected to the cover 312. The mount frame 313 is assembled with the mount seat 50 via bolts (not shown), such that the base 311 of the liquid cooling plate 30 is thermally coupled to the heat source 20.

In this embodiment, the base 311 and the cover 312 together form a fluid chamber S1 for accommodating a coolant C, where the coolant C may be a fluid which is clean and impurity-free and has low viscosity, good thermal conductivity, such as PG25 or PG55. The cover 312 has an inlet 3121, an outlet 3122, a recess 3123 and a plurality of mount pillars 3124. The inlet 3121 and the outlet 3122 communicate with the fluid chamber S1. The recess 3123 is recessed from an inner surface of the cover 312 forming the fluid chamber S1, and is located between the inlet 3121 and the outlet 3122. The mount pillars 3124 protrude from an inner surface of the recess 3123.

The flexible partition 32 includes a main part 321 and two mount parts 322. The mount parts 322 are respectively connected to two opposite sides of the main part 321, and each of the mount parts 322 has two mount holes 3221. The mount holes 3221 of the mount parts 322 of the flexible partition 32 are respectively assembled with the mount pillars 3124 of the cover 312, such that the flexible partition 32 is mounted in the recess 3123 of the cover 312. The main part 321 of the flexible partition 32 surrounds and forms an enclosed gas chamber S2 in the recess 3123 alone, and the gas 33 is accommodated in the gas chamber S2.

Note that the quantity of the mount holes 3221 of each of the mount parts 322 is not restricted to being two and may be modified to be one or greater than two in other embodiments. Moreover, the quantity of the mount parts 322 of the flexible partition 32 is not restricted to being two and may be modified to be one in other embodiments.

In addition, the flexible partition 32 is not restricted to being fixed in the recess 3123 of the cover 312 via the cooperation of the mount holes 3221 of the mount parts 322 and the mount pillars 3124 of the cover 312. In some other embodiments, the flexible partition may not have the mount parts, the cover may not have the mount pillars, and the main part may be fixed in the recess of the cover via a tight fit manner.

The fin assembly 34 is located in the fluid chamber S1 and protrude from an inner surface of the base 311 forming the fluid chamber S1. The fin assembly 34 is configured to help the liquid cooling plate 30 to transfer heat generated by the heat source 20 to the coolant C. The joints 35 and 36 are respectively disposed at the inlet 3121 and the outlet 3122, and are respectively connected to pipes P1 and P2. The pipe P1 is, for example, connected to a coolant driver 200 in the cabinet 100 (as shown in FIG. 1), and the pipe P2 is, for example, connected to a radiator (not shown) in the cabinet 100. The coolant driver 200 can drive the coolant C to flow into the fluid chamber S1 through the pipe P1 and the joint 35 disposed at the inlet 3121 so as to absorb heat. The coolant C flowing out of the fluid chamber S1 from the outlet 3122 can flow to the radiator through the joint 36 disposed at the outlet 3122 and the pipe P2 for being cooled, and then the coolant C can flow back to the coolant driver 200.

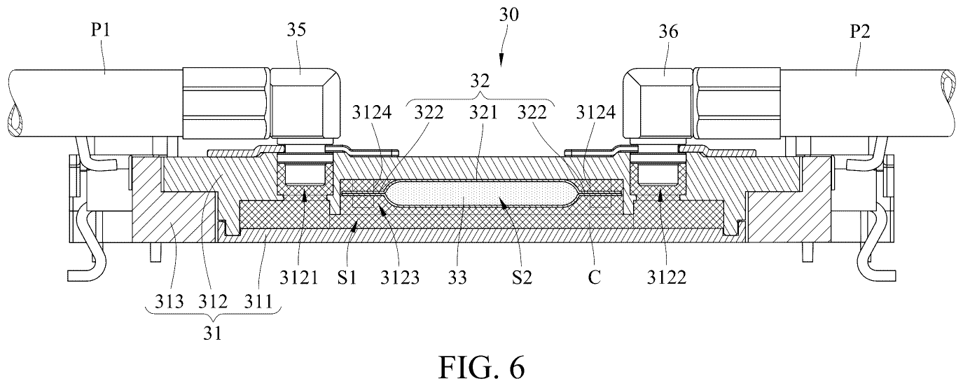

Then, referring to FIGS. 5 and 6, FIG. 6 is a cross-sectional view of the liquid cooling plate in FIG. 5 when a coolant in the liquid cooling plate is frozen.

In this embodiment, the server 1 may be transported via an aircraft while the liquid cooling plate 30 is fully filled with the coolant C. During the air transportation of the server 1, the environment temperature is extremely low, such that the coolant C in the liquid cooling plate 30 is frozen so as to cause the volume of the coolant C to increase. As shown in FIG. 6, the liquid cooling plate 30 is provided with the recess 3123 therein, and the flexible partition 32 of the liquid cooling plate 30 forms the gas chamber S2 in the recess 3123 for accommodating the gas 33. Therefore, when the coolant C in the liquid cooling plate 30 is frozen, the frozen coolant C forces the flexible partition 32 to compress the gas 33 in the gas chamber S2 for absorbing the volume expansion of the coolant C, thereby preventing the liquid cooling plate 30 from being damaged by the frozen coolant C which has volume expansion. As a result, even if the coolant is selected from a liquid which has better viscosity and thermal conductivity but higher freezing point so as to be easily frozen, the liquid cooling plate 30 is ensured not to be damaged by the coolant C which is frozen and has volume expansion.

In this embodiment, the gas 33 in the gas chamber S2 formed by the flexible partition 32 is, for example, selected from a gas which is compressible and has chemical stability. For example, the gas 33 may be inert gas, such as helium. The compression factor of helium is approximately 1 in normal temperature and pressure which is similar to an ideal gas, which approves its compressibility. In addition, helium is non-toxic, chemically inert and light.

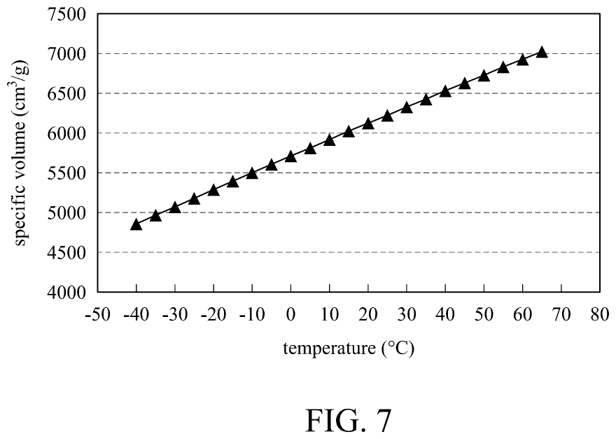

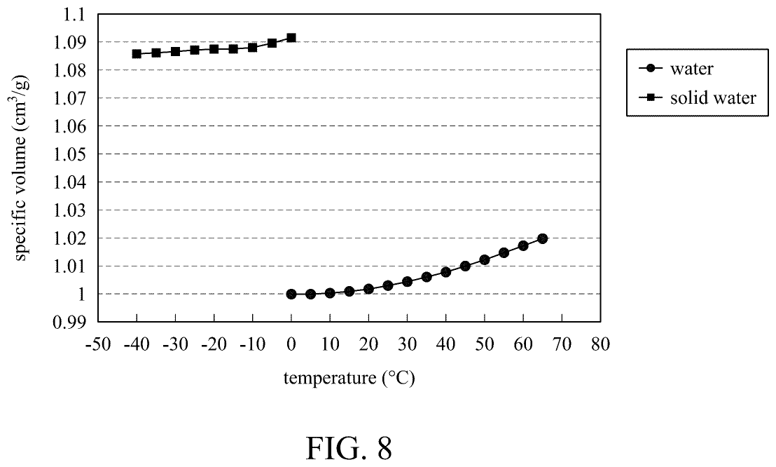

In general, the operation temperature of a liquid cooling system falls within a range from −40° C. to 65° C. Assuming that the gas 33 is helium, and the coolant C is water, the relationship between volume and the temperature of them can be obtained from specific volume in different temperature. Referring to FIGS. 7 and 8, FIG. 7 is a curve chart showing a relationship between specific volume of helium and temperature, and FIG. 8 is a curve chart showing a relationship between specific volume of water and temperature. The specific volume is defined as volume per unit mass, and can be represented by the equation

$$v = \frac{V}{m} ,$$

where ν is denoted as specific volume (cm³/g), V is denoted as volume (cm³), and m is denoted as mass (g). As shown in FIG. 7, the volume of helium decreases as temperature decreases. As shown in FIG. 8, the volume of water decreases as temperature decreases in the range from 65° C. to 4° C. However, the volume of water increases as temperature decreases in the range from 4° C. to 0° C., and the volume of water increase about 9% when frozen in 0° C.

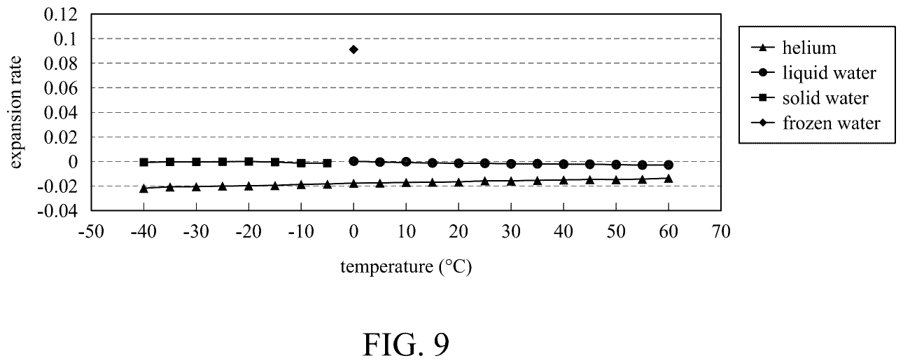

Then, referring to FIG. 9, FIG. 9 is a curve chart showing a relationship between expansion rates of helium and water and temperature. The expansion rate is a ratio of variation of volume of an object to original volume of the object and can be represented by the equation

$$α = \frac{{V}_{1} - {V}_{0}}{{V}_{0}} ,$$

where α is denoted as expansion rate, V₀ is denoted as original volume, and V₁ is denoted as changed volume. As shown in FIG. 9, the variation of the expansion rates of the liquid water in 4° C. to 0° C. and the solid water in −5° C. to −40° C. is extremely small, and the shrinkage rate of helium is greater than the expansion rates of the liquid water and the solid water in 4° C.-0° C. and 0° C. to −40° C., and thus the variation of the volume of the water when frozen in 0° C. is the main consideration.

Since the volume of frozen water in 0° C. increases about 9%, it can be obtained that 1 ml water will cause the volume to increase 0.09 ml after frozen. Assuming that the volume of the fluid chamber S1 in the liquid cooling plate 30 is about 25 ml, the volume of the gas chamber S2 is at least greater than 2.25 ml. Assuming that the volume of the gas chamber S2 is about 2.5 ml in normal temperature and pressure, the pressure in the gas chamber S2 may increase to about 9 atm when the water is frozen in 0° C. and compresses the gas chamber S2 (e.g., obtained from Ideal Gas Law, PV=nRT).

In this embodiment, the flexible partition 32 may be made of a material which does not cause chemical compatible issue with the coolant. For example, the flexible partition 32 may be made of plastic material, such as high density polyethylene material. High density polyethylene material is a common plastic film material with good ductility, high corrosion resistance and low thermal expansion rate and water absorption rate. High density polyethylene material is suitable for a temperature range from −40° C. to 90° C., which meets the air transportation condition of −40° C. The compressive strength and tensile strength of the high-density polyethylene material are both about 200 atm, which is greater than the pressure of the coolant C flowing in the liquid cooling plate 30 and the maximum pressure that the frozen coolant C applied on the flexible partition 32.

Note that the flexible partition 32 is not restricted to being made of plastic material. In other embodiments, flexible partition may be made of rubber material, such as ethylene propylene diene monomer, which has an applicable temperature range meeting the operation of the liquid cooling plate, low expansion rate and low water absorption rate and high corrosion resistance, and thus is suitable to be the material forming the gas chamber.

In this embodiment, compared to the cost to arrange additional pipelines connected to the liquid cooling plate for increasing space to accommodate the coolant, the cost derived from additionally arranging the flexible partition 32 in the liquid cooling plate 30 and filling the gas 33 into the gas chamber S2 formed by the flexible partition 32 is relatively lower, thereby saving cost.

In this embodiment, the recess 3123 in the liquid cooling plate 30 for accommodating the flexible partition 32 is formed on the cover 312, but the disclosure is not limited thereto. In other embodiments, the recess may be formed at any position of the liquid cooling plate. For example, the recess may be formed at the base of the liquid cooling plate, such as the bottom or side wall of the base as long as the flexible partition in the recess does not affect the flowing of the coolant.

Note that the gas 33 in the gas chamber S2 formed by the main part 321 of the flexible partition 32 may be manually exhausted or replenished. For example, an air valve (e.g., a ball valve) may be provided on the main part 321 of the flexible partition 32 for manually exhausting the gas 33 out of the gas chamber S2 or replenishing the gas 33 into the gas chamber S2.

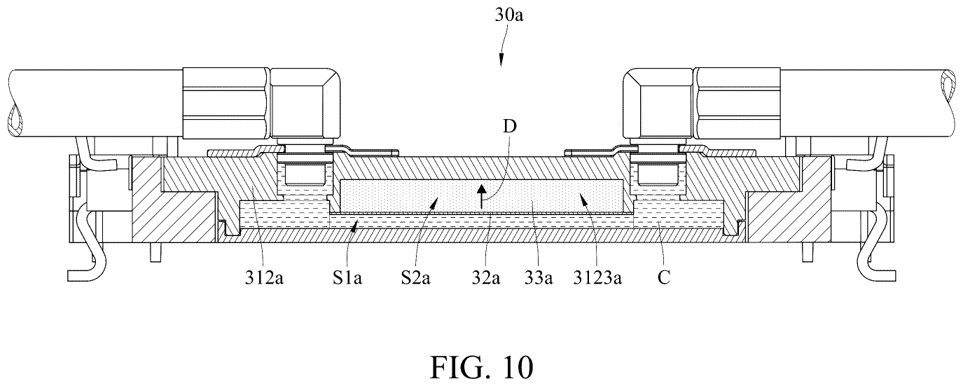

Then, referring to FIG. 10, FIG. 10 is a cross-sectional view of a liquid cooling plate according to a second embodiment of the disclosure

The liquid cooling plate 30a of this embodiment is similar to the liquid cooling plate 30 of the previous embodiment, the main difference between them is how the flexible partition form the gas chamber, and thus the following descriptions mainly introduce such difference while the same parts between them will not repeatedly introduced hereinafter.

In this embodiment, a flexible partition 32a of the liquid cooling plate 30a is in a sheet shape, and is, for example, made of rubber material or plastic material, where the rubber material may be ethylene propylene diene monomer, and the plastic material may be fluorinated ethylene propylene, polytetrafluoroethene or polyetheretherketone. The flexible partition 32a is fixed to an inner surface of a fluid chamber Sla of the liquid cooling plate 30a. For example, the flexible partition 32a is fixed to an inner surface of the cover 312a forming the fluid chamber S1a. The gas chamber S2a is formed by the flexible partition 32a and an inner surface of a recess 3123a. A gas 33a in the gas chamber S2a may be a gas which is compressible and has chemical stability, such as air. When the coolant C is frozen in the liquid cooling plate 30a, the frozen coolant C forces the flexible partition 32a to compress the gas 33a in the gas chamber S2a, for example, along a direction D for absorbing the volume expansion of the coolant C, thereby preventing the liquid cooling plate 30a from being damaged by the frozen coolant C which has volume expansion.

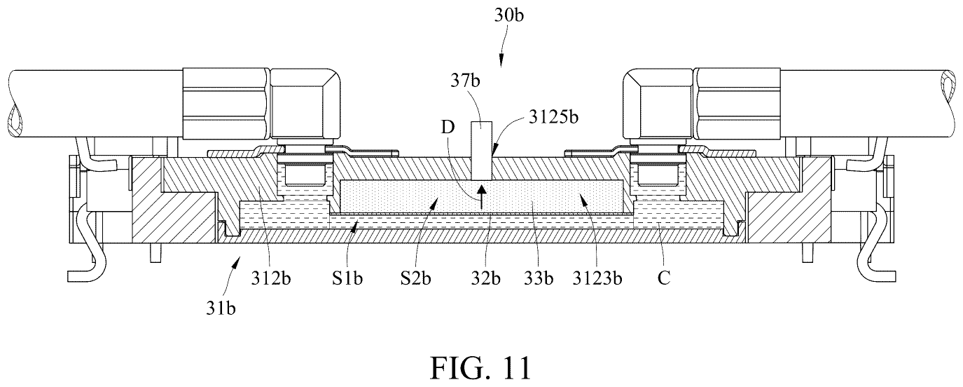

Then, referring to FIG. 11, FIG. 11 is a cross-sectional view of a liquid cooling plate according to a third embodiment of the disclosure.

The liquid cooling plate 30b of this embodiment is similar to the liquid cooling plate 30a of the previous embodiment, the main difference between them is whether the gas chamber formed by the flexible partition communicates with outside or not, and thus the following descriptions mainly introduce such difference while the same parts between them will not repeatedly introduced hereinafter.

In this embodiment, a housing 31b of the liquid cooling plate 30b further has a through hole 3125b. For example, the through hole 3125b is located at a cover 312b of the housing 31b, and the recess 3123b communicates with outside through the through hole 3125b. In addition, the liquid cooling plate 30b may further include a valve 37b. The valve 37b is, for example, an air valve, such as an automatic air valve. The valve 37b is disposed in the through hole 3125b for controlling a communication relationship between a gas chamber S2b formed in the recess 3123b by a flexible partition 32b and an external environment. When the coolant C in a fluid chamber S1b of the liquid cooling plate 30b is frozen, the frozen coolant C forces the flexible partition 32b to compress a gas 33b in the gas chamber S2b, for example, along a direction D for driving the valve 37b to open automatically to communicate the gas chamber S2b with outside. Therefore, the compressed gas 33b in the gas chamber S2b exhaust to outside, which absorbs the volume expansion of the coolant C for preventing the liquid cooling plate 30b from being damaged by the frozen coolant C which has volume expansion. On the other hand, when the gas 33b in the gas chamber S2b is insufficient, the valve 37b may automatically open for allowing the gas 33b to be replenished in the gas chamber S2b.

In this embodiment, the valve 37b is not restricted to being the automatic air valve. In other embodiments, the valve may be another type of air valve, which automatically open when the coolant in the fluid chamber is frozen only, but does not automatically open when the gas in the gas chamber is insufficient. In such a case, an additional valve may be provided on the cover of the housing, and this valve may be a ball valve for manually replenishing the gas in the gas chamber. On the other hand, the valve 37b is an optional component and may be omitted in other embodiments. In such a configuration, the gas chamber may constantly communicate with outside through the through hole, and the gas in the gas chamber may be selected from air.

According to the liquid cooling plates and the server as discussed in the above embodiments, the liquid cooling plate is provided with the recess therein, and the flexible partition of the liquid cooling plate forms the gas chamber in the recess for accommodating the gas. Therefore, when the coolant in the liquid cooling plate is frozen, the frozen coolant forces the flexible partition to compress the gas in the gas chamber for absorbing the volume expansion of the coolant, thereby preventing the liquid cooling plate from being damaged by the frozen coolant which has volume expansion. As a result, even if the coolant is selected from a liquid which has better viscosity and thermal conductivity but higher freezing point so as to be easily frozen, the liquid cooling plate is ensured not to be damaged by the coolant which is frozen and has volume expansion.

Moreover, compared to the cost to arrange additional pipelines connected to the liquid cooling plate for increasing space to accommodate the coolant, the cost derived from additionally arranging the flexible partition in the liquid cooling plate and filling the gas into the gas chamber formed by the flexible partition is relatively lower, thereby saving cost.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A liquid cooling plate, comprising:
a housing, having a fluid chamber, an inlet, an outlet and a recess, wherein the inlet and the outlet communicate with the fluid chamber, and the recess is recessed from an inner surface of the fluid chamber; and
a flexible partition, forming a gas chamber in the recess.

2. The liquid cooling plate according to claim 1, wherein the flexible partition surrounds and forms the gas chamber in the recess alone, and the gas chamber is enclosed.

3. The liquid cooling plate according to claim 2, wherein the flexible partition comprises a main part and at least one mount part connected to each other, the gas chamber is located in the main part, the at least one mount part has at least one mount hole, the housing further has at least one mount pillar, and the at least one mount pillar protrudes from an inner surface of the recess and is disposed through the at least one mount hole.

4. The liquid cooling plate according to claim 1, wherein the flexible partition is in a sheet shape, the flexible partition is fixed to the inner surface of the fluid chamber, and the gas chamber is formed by the flexible partition and an inner surface of the recess.

5. The liquid cooling plate according to claim 4, wherein the housing further has a through hole, and the recess communicates with outside through the through hole.

6. The liquid cooling plate according to claim 5, further comprising a valve, wherein the valve is disposed in the through hole.

7. The liquid cooling plate according to claim 1, wherein the flexible partition is made of plastic material.

8. The liquid cooling plate according to claim 1, wherein the flexible partition is made of rubber material.

9. The liquid cooling plate according to claim 1, wherein the housing comprises a cover and a base assembled with each other, the cover and the base together form the fluid chamber, and the inlet, the outlet and the recess are located at the cover.

10. The liquid cooling plate according to claim 9, wherein the recess is located between the inlet and the outlet.

11. The liquid cooling plate according to claim 1, further comprising a gas, wherein the gas is helium and is filled in the gas chamber.

12. A server, comprising:
a motherboard;
a heat source, disposed on the motherboard; and
a liquid cooling plate, thermally coupled to the heat source and comprising:
a housing, having a fluid chamber, an inlet, an outlet and a recess, wherein the inlet and the outlet communicate with the fluid chamber, and the recess is recessed from an inner surface of the fluid chamber; and
a flexible partition, forming a gas chamber in the recess.

13. The server according to claim 12, wherein the flexible partition surrounds and forms the gas chamber in the recess alone, and the gas chamber is enclosed.

14. The server according to claim 13, wherein the flexible partition comprises a main part and at least one mount part connected to each other, the gas chamber is located in the main part, the at least one mount part has at least one mount hole, the housing further has at least one mount pillar, and the at least one mount pillar protrudes from an inner surface of the recess and is disposed through the at least one mount hole.

15. The server according to claim 12, wherein the flexible partition is in a sheet shape, the flexible partition is fixed to the inner surface of the fluid chamber, and the gas chamber is formed by the flexible partition and an inner surface of the recess.

16. The server according to claim 15, wherein the housing further has a through hole, and the recess communicates with outside through the through hole.

17. The server according to claim 16, wherein the liquid cooling plate further comprises a valve, and the valve is disposed in the through hole.

18. The server according to claim 12, wherein the flexible partition is made of plastic material.

19. The server according to claim 12, wherein the flexible partition is made of rubber material.

20. The server according to claim 12, wherein the housing comprises a cover and a base assembled with each other, the cover and the base together form the fluid chamber, and the inlet, the outlet and the recess are located at the cover.
